(19) United States
(12) Patent Application Publication
(10) Pub. No.: US 2009/0092805 A1
(43) Pub. Date: Apr. 9, 2009

(54) Ferroelectric Material With Polarization Pattern

(75) Inventors: Tong Zhao, Pittsburgh, PA (US); Andreas Karl Roelofs, Eden Prairie, MN (US); Florin Zavaliche, Pittsburgh, PA (US); Philip George Pitcher, Cranberry Township, PA (US)

Correspondence Address: PIETRAGALLO GORDON ALFANO BOSICK & RASPANTI, LLP, ONE OXFORD CENTRE, 38TH FLOOR, 301 GRANT STREET, PITTSBURGH, PA, 15219-6404, US

(73) Assignee: Seagate Technology LLC, Scotts Valley, CA (US)

(21) Appl. No.: 11/866,443

(22) Filed: Oct. 3, 2007

(51) Int. Cl. B32B 5/14; C23C 14/48; C23C 14/28

(52) U.S. Cl. 428/212; 427/595; 427/523

(57) ABSTRACT

An apparatus includes a ferroelectric layer and a polarization pattern configured in the ferroelectric layer to represent position data. The polarization pattern has a switchable polarization state domain and an unswitchable polarization state domain. A method includes providing a ferroelectric layer and establishing a polarization pattern in the ferroelectric layer to represent position data.

### BACKGROUND

In devices that need to store information such as, for example, data storage devices, user data is typically stored on tracks of a storage media. In addition to the user data, position data is also provided on the storage media. The position data can include servo marks that, when read, generally indicate position coordinates (e.g. X, Y coordinates, track number, or sector number) of a transducer relative to the storage media surface. Such devices also include a servo system that positions the transducer over a selected track based on feedback of the position data. The servo system may have a “seek mode” that moves the transducer from one track to another track based on reading the servo marks. The servo system also may have a “tracking mode” in which the transducer is precisely aligned with a selected track based on a reading of the servo marks.

At the time of manufacture of a magnetic data storage device, the servo marks are provided on the storage media. During operational use of the magnetic data storage device, the transducer reads the servo marks but there is typically no need to erase and rewrite servo data during operation. The position of servo marks on the media for a magnetic data storage device is therefore stable and does not change significantly during the operational life of the data storage device.

Data storage devices are being proposed to provide smaller size, higher capacity, and lower cost data storage devices. One particular example of such a data storage device is a probe storage device. The probe storage device may include one or more transducers (e.g. one or more probes), that each includes a conductive element (e.g., an electrode), which are positioned adjacent to and in contact with a ferroelectric thin film storage media. User data is stored in the media by causing the polarization of the ferroelectric film to point “up” or “down” in a spatially small domain local to a tip of the transducer by applying suitable voltages to the transducer through the conductive element. Data can then be read by, for example, sensing current flow during polarization reversal.

For probe storage devices, position data can be polarized on the ferroelectric storage media. However, the characteristics of probe storage do not permit stable positioning of the position data. When data is read from a ferroelectric storage media with a transducer, the conventional process of reading the data inherently erases or removes the data from the media. An electronic circuit that provides the read operation for a probe storage device must follow up and automatically provide a subsequent write operation of the same data in order to avoid loss of the data on the ferroelectric storage media. This is not an insurmountable problem for user data. However, with position data (e.g. servo marks) the repeated reading and automatic rewriting of position data will inevitably lead to loss of accurate position information. This instability and loss of accurate position information limits the useful life of the probe storage device. Adjacent tracks on the ferroelectric storage media with user data will become misaligned due to creep of the position data and user data tracks will eventually overwrite or interfere with one another.

### SUMMARY

An aspect of the present invention is to provide an apparatus having a ferroelectric layer and a polarization pattern configured in the ferroelectric layer to represent position data. The polarization pattern has a switchable polarization state domain and an unswitchable polarization state domain.

Another aspect of the present invention is to provide an apparatus including a first ferroelectric region and a second ferroelectric region adjacent the first ferroelectric region. The first region has a plurality of first domains that each has a switchable polarization state. The second region has a plurality of second domains that includes: a switchable polarization state domain and an unswitchable polarization state domain.

A further aspect of the present invention is to provide a method that includes providing a ferroelectric layer and establishing a polarization pattern in the ferroelectric layer to represent position data. The polarization pattern is established to have a switchable polarization state domain and an unswitchable polarization state domain.

These and various other features and advantages will be apparent from a reading of the following detailed description.

### DRAWINGS

FIG. 1 is a schematic cross-sectional view of a device, according to one aspect of the present invention.

FIG. 2 is a top schematic view of a ferroelectric storage media, according to one aspect of the present invention.

FIG. 3A is a schematic cross-sectional view taken along line 3A-3A of FIG. 2.

FIG. 3B corresponds to FIG. 3A and graphically illustrates current flow as a result of polarization reversal for an applied voltage signal, according to one aspect of the present invention.

FIG. 4 illustrates a hysteresis loop of polarization of a ferroelectric material that is not imprinted (solid line) and of a ferroelectric material that is imprinted (dashed line), according to one aspect of the present invention.

FIG. 5 graphically illustrates current versus voltage for a ferroelectric imprint of a ferroelectric material, according to one aspect of the present invention.

FIG. 6 illustrates a hysteresis loop of polarization of a ferroelectric material that has not been ion implanted (solid line) and of a ferroelectric material that has been ion implanted (dashed line), according to one aspect of the present invention.

FIG. 7 graphically illustrates piezoresponse versus voltage for the ion implantation of a ferroelectric material, according to one aspect of the present invention.

### DETAILED DESCRIPTION

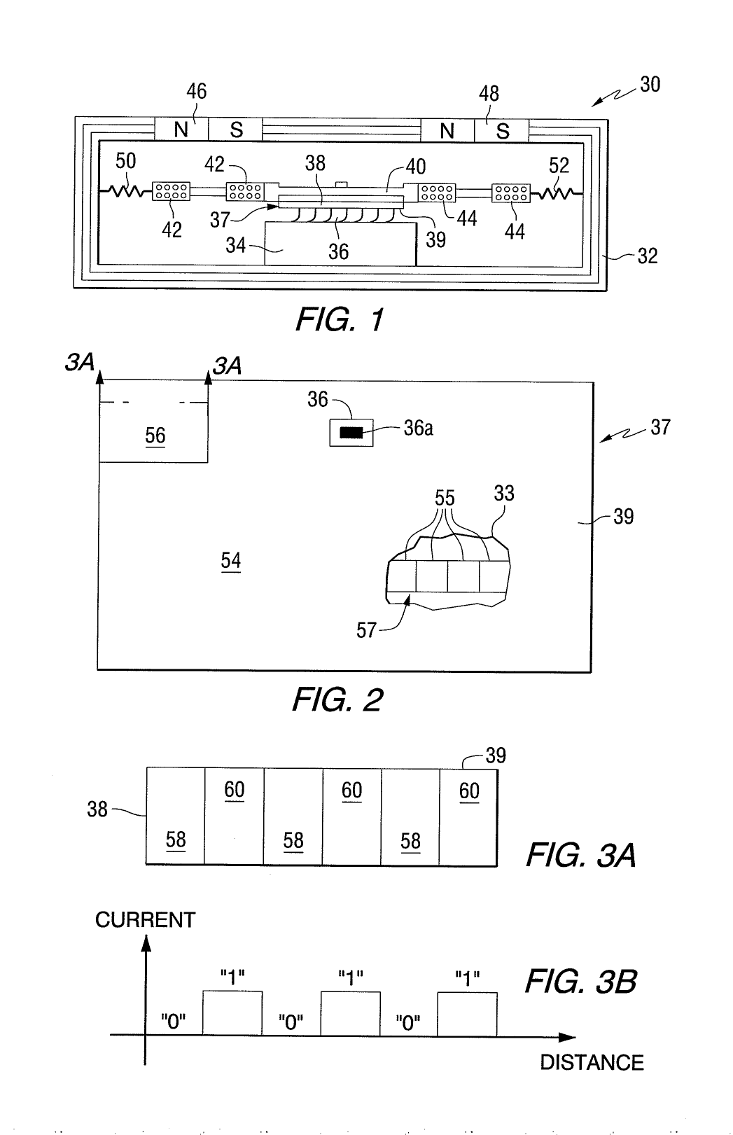

FIG. 1 is a schematic cross-sectional view of a device 30 constructed in accordance with the invention. The device 30 includes an enclosure 32 (which also may be referred to as a case, base, or frame) that contains a substrate 34. An array of transducers 36, which in accordance with one aspect of the invention may be an array of “probes,” is positioned on the substrate 34. The transducers 36 extend upward to make contact with a ferroelectric storage media 37 which includes a ferroelectric storage layer 38 formed of, for example, lead zirconium titanate (PZT). The storage media 37 also includes a media surface 39. The storage media 37 is mounted on a movable member 40 (which also may be referred to as a sled). Coils 42 and 44 are mounted on the movable member 40. Magnets 46 and 48 are mounted in the enclosure 32 near the coils 42 and 44, respectively. Springs 50 and 52 form part of a suspension assembly that supports the movable member 40. It will be appreciated that the combination of coils 42 and 44 and magnets 46 and 48 forms an actuator assembly that is used to move the movable member 40. Electric current in the coils 42 and 44 creates a magnetic field that interacts with the magnetic field produced by the magnets 46 and 48 to produce a force that has a component in the plane of the movable member 40 and causes linear movement of the movable member 40. This movement in turn causes individual storage locations or domains on the media 37 to be moved relative to the transducers 36.

While FIG. 1 illustrates an example of one aspect of the invention, it will be appreciated that the invention is not limited to any particular configuration or associated components. For example, the transducers 36 can be arranged in various configurations relative to the media 37. In addition, other types of actuator assemblies, such as, for example, electrostatic actuators, could provide the relative movement between the transducers 36 and the media 37.

FIG. 2 is a top schematic view of the ferroelectric storage media 37 in accordance with an aspect of the invention. The media surface 39 is accessible by a scanning motion of the transducers 36 and in particular by a tip 36a of the transducers 36, wherein only a single transducer 36 and corresponding tip 36a are schematically shown in FIG. 2 for illustration purposes. The storage media 37 includes a first media region 54 for storing user data. The first media region 54 includes a plurality of first domains 55 having a switchable (i.e. rewritable for an applied voltage signal) polarization state. The domains 55 are schematically shown in the cutaway portion 33 of the storage media 37 that illustrates an example track 57. It will be appreciated that the domains 55 may have a polarization pointing up or down.

Still referring to FIG. 2, the storage media 37 also includes a second media region 56 that includes a plurality of second domains. The plurality of second domains includes a switchable (i.e. rewritable for the applied voltage signal) polarization state domain and an unswitchable (i.e. not rewritable for the applied voltage signal) polarization state domain, as will be described herein with reference to FIG. 3A. Position data, which also may be referred to as servo data or servo information, is stored in the second media region 56. It will be appreciated that the storage media 37 may also include additional second media regions (not shown) for storing position data at various locations on the media surface 39.

FIG. 3A is a schematic cross-sectional view taken along line 3A-3A of FIG. 2. Specifically, FIG. 3A shows a polarization pattern of unswitchable domains 58 and switchable domains 60 contained in the storage layer 38 of the storage media 37 for providing the described position data in the second media region 56. FIG. 3B corresponds to FIG. 3A and graphically illustrates current flow for polarization reversal when a voltage signal (e.g. a readback voltage signal) is applied to the storage media 37. The unswitchable domains 58 do not switch for the applied signal and, thus, provide either no measurable current flow or a current flow lower than what occurs for the switchable domains 60 at the applied signal. The unswitchable domains 58 are represented by a binary “0”. The switchable domains 60 do switch for the applied signal and, thus, provide a measurable current flow. The switchable domains 60 are represented by a binary “1”. The resulting position data polarization pattern for this example is, therefore, 0-1-0-1-0-1. The polarization pattern is recognizable by the servo system that positions the transducer 36 relative to the storage media 37 based on the feedback of the position data. It will be appreciated that various polarization patterns may be provided in accordance with the invention by providing various combinations of unswitchable domains 58 and switchable domains 60.

In accordance with the invention, the switchable polarization state domains 55 contained in the first media region 54 and the switchable polarization state domains 60 contained in the second media region 56 are both switchable for an applied voltage signal (e.g., a readback voltage signal). The unswitchable polarization state domains 58 contained in the second media region 56 will not switch for the same applied voltage signal that is used to switch the domains 55 and 60. Thus, read/write operations performed by the transducer 36 will not affect the unswitchable domains 58 that make up a part of the position data. Therefore, it will be appreciated that when aspects of the invention are used to form a storage media 37, the read/write electronic circuit used in the storage device only needs to have the ability to apply a voltage signal to switch the domains 55 and 60 in order to provide for both readback operations and identifying read position data or servo information that is contained in the second media region 56.

After the position data has been read and processed, a voltage signal with the opposite polarity as to the signal used to read the position data will be applied to the second media region 56 to reset the switchable domains 60 to their original polarization state; the polarization state in the unswitchable domains 58 will not be affected. Advantageously, this provides for the position data polarization pattern to be reset.

In order to establish the second media region 56 having the described unswitchable domains 58 and switchable domains 60 to represent position data, the selected domains that need to be unswitchable domains 58 must be made unswitchable. This is done at the time of manufacture of the storage media 37 by, for example, ferroelectric imprint or ion implantation processes, which will each be described in more detail below.

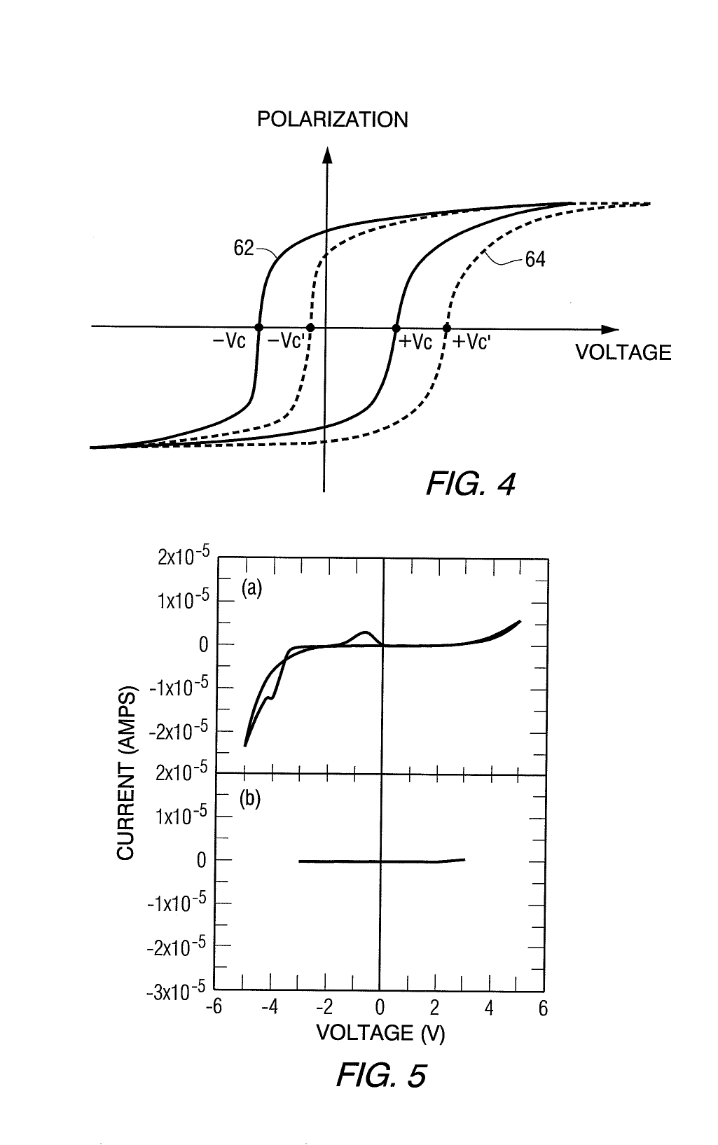

Referring to FIG. 4, the use of ferroelectric imprint to establish unswitchable domains 58 will be described. Imprinting generally refers to the ability to produce a voltage shift in the hysteresis polarization-voltage loops of ferroelectric materials such as, for example, lead zirconate titanate (PZT) or strontium bismuth tantalate (SBT). Imprinting is accomplished by the application of energy to a selected area, such as the area that makes up domains 58. The energy can be, for example, in the form of applying ultraviolet (UV) radiation or heat to the ferroelectric material.

Still referring to FIG. 4, there is illustrated a typical hysteresis loop 62 (shown in solid line) for a ferroelectric material that is not imprinted. A horizontal axis represents voltage and a vertical axis represents polarization. The hysteresis loop 62 illustrates that for the chosen ferroelectric material a symmetric coercive voltage, Vc, must be applied on the positive voltage side (+Vc) or negative voltage side (−Vc) to switch the polarization.

FIG. 4 also illustrates a typical hysteresis loop 64, shown in dashed line, for a ferroelectric material that has been imprinted. Imprinting results in the coercive voltage, Vc, of the ferroelectric material being increased either at the positive voltage side (+Vc′) or at the negative voltage side (−Vc′). The polarization of the imprinted material becomes unswitchable for an applied voltage that is less than the increased coercive voltage, wherein the increased coercive voltage value is the larger of |+Vc′| and |−Vc′| (i.e. the absolute value of +Vc′ and −Vc′). For the example shown in FIG. 4, the loop 64 is shifted to the right or positive voltage side and, therefore, the coercive voltage is increased on the positive voltage side (+Vc′) and the increased coercive voltage is |+Vc′|. The imprinting in this example results in an increased coercive voltage at the positive voltage side and a decreased coercive voltage at the negative voltage side, i.e. |+Vc′|>|Vc|, and |−Vc′|<|Vc|. Thus, if such an imprint is applied to the domains 58 they would have a corresponding coercive voltage of |+Vc′|. The domains 60 would maintain the coercive voltage, Vc. Then, for an applied voltage signal, V, such that |Vc|<|V|<|+Vc′|, the polarization of the domains 58 would not switch but the polarization of the domains 60 would switch. In addition, the hysteresis loop shifting to the positive voltage side in the domains 58 also means the polarization is stabilized in the negative direction by the imprinting. Therefore, a negative voltage, V, will not cause the polarization of the domains 58 to switch because the polarization is already in the negative direction; a positive voltage, V, is not able to switch the polarization of the domains 58 from negative to positive because the positive voltage, V, is smaller than +Vc′.

It will be appreciated that in accordance with the invention the loop 64 may be shifted to the negative voltage side rather than shifting to the positive voltage side as described hereinabove. When the loop 64 is shifted to the negative voltage side, an increased coercive voltage is expected at the negative voltage side while a reduced coercive voltage is expected at the positive voltage side, i.e. |−Vc′|>|+Vc′|. In such a case, for an applied voltage signal, V, such that |Vc|<|V|<|−Vc′|, the polarization of the domains 58 would not switch but the polarization of the domains 60 would switch. As an example, FIG. 5 illustrates the results of a ferroelectric imprint for a 30 nm thick layer of PZT ferroelectric material wherein the coercive voltage has been increased to the negative voltage side. The imprint was done by rapid thermal annealing at 500° C. for one minute in an argon environment. The typical coercive voltage for a non-imprinted 30 nm thick layer of PZT ferroelectric material is about 2V or less. Thus, by applying a voltage between about −3V and about +3V the non-imprinted area would be switched and the imprinted area would not be switched. The top portion (a) of FIG. 5 shows that because the ferroelectric hysteresis is shifted to the negative voltage part due to the imprint that a negative voltage larger than about −4V would be needed to switch the polarization to the negative direction. The bottom portion (b) of FIG. 5 shows the current response of an imprinted area for an applied voltage between −3V and +3V. As shown, the current is 0 meaning that there was no switching, i.e. no polarization reversal, for the range of voltages applied between −3V and +3V. Ferroelectric hysteresis measurements after 10⁶ cycles of electrical voltage between −3V to +3V have been determined to be similar to the measurements illustrated in the bottom portion (b) of FIG. 5. This is advantageous when the invention is used, for example, in data storage devices that generally experience high use cycles.

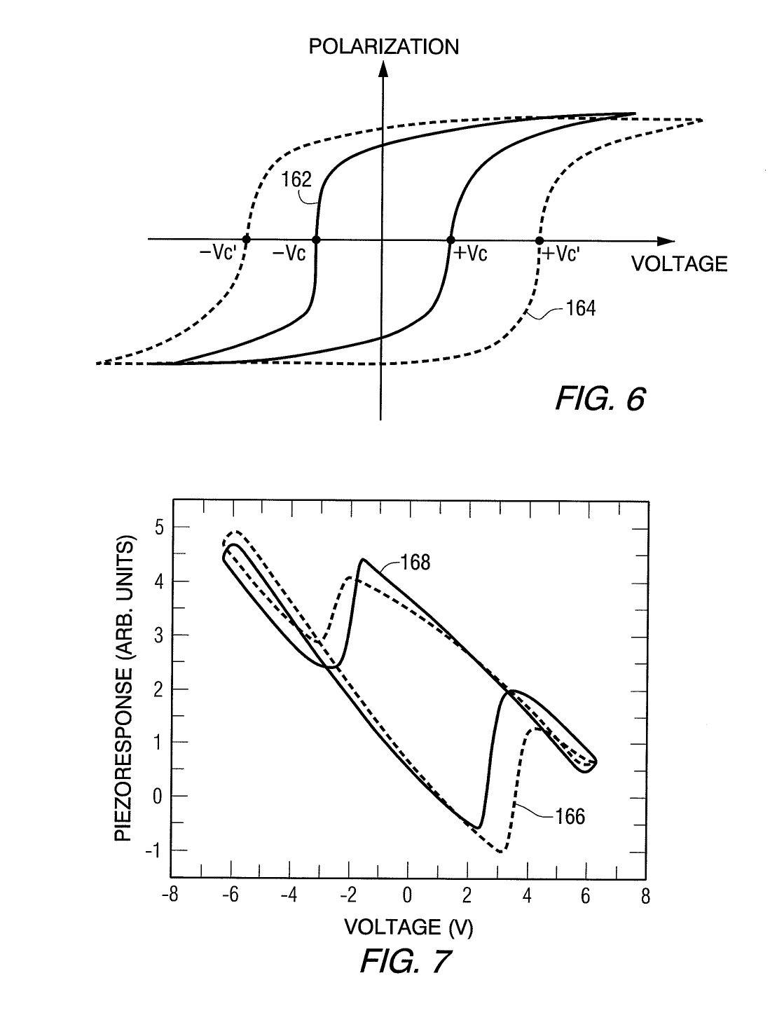

Referring to FIGS. 6 and 7, the use of ion implantation to establish unswitchable domains 58 will be described. Ion implantation generally involves producing localized regions of differential electrical activity in the ferroelectric material. The implantation results in the coercive voltage of the ferroelectric material being increased and the polarization of the material being stabilized or unswitchable for an applied voltage that is less than the increased coercive voltage value.

FIG. 6 illustrates a typical hysteresis loop 162, shown in solid line, for a ferroelectric material that has not been ion implanted. A horizontal axis represents voltage and a vertical axis represents polarization. The hysteresis loop 162 illustrates that for the chosen ferroelectric material a coercive voltage, Vc, must be applied to switch the polarization. FIG. 6 also illustrates a typical hysteresis loop 164, shown in dashed line, for a ferroelectric material that has been ion implanted. The hysteresis loop 164 illustrates that for the ion implanted ferroelectric material a coercive voltage, Vc′, must be applied to switch the polarization. The ion implantation results in an increased coercive voltage, i.e. Vc′>Vc. Thus, if ion implantation is applied to the domains 58 they would have a corresponding coercive voltage, Vc′. The domains 60 would maintain the coercive voltage, Vc. For an applied voltage signal, V, such that Vc<V<Vc′, the polarization of the domains 58 would not switch but the polarization of the domains 60 would switch.

FIG. 7 illustrates the results of ion implantation for a PZT ferroelectric material having a thickness of about 30 nm. Specifically, oxygen was implanted into the PZT material that produced an increase in coercive voltage. The implant induced increase in coercive voltage is demonstrated through a comparison of piezoelectric d₃₃ hysteresis between an oxygen implanted region (dashed line 166) and a non-implanted region (solid line 168) of a PZT film. As shown in FIG. 7, the coercive voltage for the implanted region, as indicated by dashed line 166, is higher than the coercive voltage for the non-implanted region, as indicated by solid line 168.

The invention encompasses the method of providing a ferroelectric layer (e.g., ferroelectric storage layer 38), and establishing a polarization pattern in the ferroelectric layer to represent position data. The polarization pattern includes at least one switchable polarization state domain (e.g., domains 60) and at least one unswitchable polarization state domain (e.g., 58). The unswitchable polarization state domains may be established by, for example, ferroelectric imprint or ion implantation, as described herein. The invention also includes a plurality of domains (e.g., domains 55) wherein each of these domains has a switchable polarization state. The plurality of domains may represent, for example, user data.

The implementation described above and other implementations are within the scope of the following claims.

What is claimed is:

1. An apparatus, comprising:
a ferroelectric layer; and
a polarization pattern configured in the ferroelectric layer to represent position data, the polarization pattern having a switchable polarization state domain and an unswitchable polarization state domain.

2. The apparatus of claim 1, wherein a polarization of the switchable polarization state domain is switchable for an applied signal and a polarization of the unswitchable polarization state domain is not switchable at the applied signal.

3. The apparatus of claim 1, wherein the switchable polarization state domain has a coercive voltage that is less than a coercive voltage of the unswitchable polarization state domain.

4. The apparatus of claim 1, wherein the ferroelectric layer is configured as a data storage layer.

5. The apparatus of claim 4, wherein the ferroelectric layer further comprises a plurality of domains each having a switchable polarization state.

6. The apparatus of claim 5, wherein the plurality of domains represents user data.

7. An apparatus, comprising:
a first ferroelectric region having a plurality of first domains that each have a switchable polarization state; and
a second ferroelectric region adjacent said first ferroelectric region, said second ferroelectric region having a plurality of second domains that includes: a switchable polarization state domain and an unswitchable polarization state domain.

8. The apparatus of claim 7, wherein the first ferroelectric region and the second ferroelectric region are configured to provide a data storage media.

9. The apparatus of claim 8, wherein the first ferroelectric region contains user data.

10. The apparatus of claim 8, wherein the second ferroelectric region contains position data.

11. The apparatus of claim 7, wherein the plurality of first domains is switchable for an applied signal.

12. The apparatus of claim 11, wherein the switchable polarization state domain of the plurality of second domains is switchable at the applied signal and the unswitchable polarization state domain of the plurality of second domains is not switchable at the applied signal.

13. The apparatus of claim 7, wherein both (i) the plurality of first domains and (ii) the switchable polarization state domain of the plurality of second domains have a coercive voltage that is less than a coercive voltage of the unswitchable polarization state domain of the plurality of second domains.

14. A method, comprising:
providing a ferroelectric layer; and
establishing a polarization pattern in the ferroelectric layer to represent position data, the polarization pattern having a switchable polarization state domain and an unswitchable polarization state domain.

15. The method of claim 14, further comprising applying a ferroelectric imprint to create the unswitchable polarization state domain.

16. The method of claim 15, further comprising selecting the ferroelectric imprint from the group of: a heat imprint or an ultraviolet radiation imprint.

17. The method of claim 14, further comprising applying ion implantation to create the unswitchable polarization state domain.

18. The method of claim 14, further comprising configuring the ferroelectric layer as a data storage layer.

19. The method of claim 14, further comprising a plurality of domains in the ferroelectric layer each having a switchable polarization state.

20. The method of claim 19, further comprising establishing the plurality of domains to represent user data.
